(19) United States
(12) Patent Application Publication
(10) Pub. No.: US 2024/0243091 A1
(43) Pub. Date: Jul. 18, 2024

(54) PHASE CHANGING THERMAL INTERFACE MATERIAL ALLOY CREATED IN-SITU

(71) Applicant: THE INDIUM CORPORATION OF AMERICA, Clinton, NY (US)

(72) Inventors: Richard McDonough, Oneida, NY (US); Milos Lazic, New Hartford, NY (US); David P. Socha, Whitesboro, NY (US)

(21) Appl. No.: 18/415,074

(22) Filed: Jan. 17, 2024

Related U.S. Application Data
(60) Provisional application No. 63/439,461, filed on Jan. 17, 2023.

(51) Int. Cl. H01L 23/00; H01L 21/48

(52) U.S. Cl. CPC H01L 24/27; H01L 21/4882; H01L 24/29; H01L 24/32; H01L 24/83; H01L 24/16; H01L 24/73; H01L 2224/16221; H01L 2224/2743; H01L 2224/29083; H01L 2224/29101; H01L 2224/29105; H01L 2224/29109; H01L 2224/29111; H01L 2224/29113; H01L 2224/29116; H01L 2224/29118; H01L 2224/29139; H01L 2224/29144; H01L 2224/29147; H01L 2224/29155; H01L 2224/29166; H01L 2224/29171; H01L 2224/2918; H01L 2224/29184; H01L 2224/32245; H01L 2224/32506; H01L 2224/73253; H01L 2224/83801; H01L 2924/01048; H01L 2924/0133

(57) ABSTRACT

Thermal interface materials deposited in solid form, in a layered manner, and their uses in electronics assembly are described. In one implementation, a method includes: forming an assembly including multiple solid metal thermal interface materials (TIMs) between a first device and a second device such that a first surface of the solid metal TIMs is in touching relation with a surface of the first device, and a second surface of the solid metal TIMs opposite the first surface is in touching relation with a surface of the second device, the solid metal TIMs including a first solid metal TIM and a second solid metal TIM; and forming a liquid TIM alloy from the solid metal TIMs by heating the assembly above a first solidus temperature of the first solid metal TIM, the liquid TIM alloy having a second solidus temperature below the first solidus temperature.

### CROSS-REFERENCE TO RELATED APPLICATIONS

The present application claims the benefit of U.S. Provisional Patent Application No. 63/439,461 filed on Jan. 17, 2023 and titled “PHASE CHANGING THERMAL INTERFACE MATERIAL ALLOY CREATED IN-SITU,” which is incorporated herein by reference in its entirety.

### DESCRIPTION OF THE RELATED ART

With the rising popularity of artificial intelligence semiconductor processors, high performance computing chips, and graphic-heavy gaming systems, efficiently removing heat from these devices remains a primary concern to achieve optimal performance of the system. Various thermal interface materials (TIMs) are currently employed to facilitate heat removal from these devices. These materials include, greases, phase change materials, metals, foils, conductive pastes and most recently, liquid metals.

Some liquid metals have both high thermal conductivity and low thermal surface resistivity. This combination makes these materials ideal for TIMs. The drawback is that liquid metals cannot be placed on a printed circuit board with a traditional pick-and-place machine. For example, indium-containing, engineered solders are shaped pieces of metal that can quite easily be placed by traditional methods with existing equipment and infrastructure. In contrast, metals in a liquid form must be dispensed or jetted onto the substrate requiring a different set of equipment.

### SUMMARY

Some implementations of the disclosure are directed to materials including phase change materials that when deposited in solid form, in a layered manner, act together to improve or maximize the thermal properties of a TIM.

In one embodiment, a method comprises: forming an assembly comprising multiple solid metal TIMs between a first device and a second device such that a first surface of the solid metal TIMs is in touching relation with a surface of the first device, and a second surface of the solid metal TIMs opposite the first surface is in touching relation with a surface of the second device, the solid metal TIMs comprising a first solid metal TIM and a second solid metal TIM; and forming a liquid TIM alloy from the solid metal TIMs by heating the assembly above a first solidus temperature of the first solid metal TIM, the liquid TIM alloy having a second solidus temperature below the first solidus temperature.

In some implementations, the second solid metal TIM has a third solidus temperature higher than the first solidus temperature of the first solid metal TIM; the first solid metal TIM becomes a first liquid metal TIM when the assembly is heated above the first solidus temperature; and forming the liquid TIM alloy comprises dissolving the second solid metal TIM in the first liquid metal TIM.

In some implementations, the multiple solid metal thermal interface materials comprise a third solid metal TIM having a fourth solidus temperature higher than the first solidus temperature of the first solid metal TIM; and forming the liquid TIM alloy comprises dissolving the second solid metal TIM and the third solid metal TIM in the first liquid metal TIM.

In some implementations, the multiple solid metal thermal interface materials comprise a third solid metal TIM including a first metal that is not soluble in the liquid TIM alloy, the first metal that is not soluble in the liquid controlling a bond line thickness of the assembly after the liquid TIM alloy is formed.

In some implementations, the third solid metal TIM further includes a second metal coating the first metal that is not soluble in the liquid TIM alloy; and forming the liquid TIM alloy comprises dissolving the second metal in the first liquid metal TIM.

In some implementations, forming the assembly comprises: placing the first solid metal TIM and the second solid metal TIM between the first device and the second device such that the first solid metal TIM is in touching relation with the second solid metal TIM; and the second solid metal TIM has a third solidus temperature higher than the first solidus temperature of the first solid metal TIM.

In some implementations, the multiple solid metal thermal interface materials comprise a third solid metal TIM having a fourth solidus temperature higher than the first solidus temperature of the first solid metal TIM; and forming the assembly comprises: placing the third solid metal between the first device and the second device such that the third solid metal TIM is in touching relation with the first solid metal TIM.

In some implementations, prior to forming the assembly, the second solid metal TIM is attached to the surface of the first device or the surface of the second device; and forming the assembly comprises: placing the first solid metal TIM in touching relation with the second solid metal TIM between the first device and the second device.

In some implementations, prior to forming the assembly, the first solid metal TIM is attached to the surface of the first device or the surface of the second device; and forming the assembly comprises: placing the second solid metal TIM in touching relation with the first solid metal TIM between the first device and the second device.

In some implementations, the liquid TIM alloy comprises In, Sn, Zn, Bi, Au, Ag, Cu, W, Ni, Cr, Mo, Ti, Cd, or Pb.

In some implementations, the first solid metal TIM comprises gallium or a gallium alloy.

In some implementations, the second solid metal TIM comprises indium or an indium alloy.

In some implementations, the multiple solid metal thermal interface materials comprise a third solid metal TIM comprising tin or a tin alloy; and the liquid TIM alloy comprises gallium, indium, and tin.

In some implementations, the first device is a heat generating device, and the second device is a heat transferring device.

In some implementations, the heat generating device is a semiconductor die, and the heat transferring device is a semiconductor package lid or heat sink.

In some implementations, forming the liquid TIM alloy from the solid metal TIMs comprises: activating the heat generating device to heat the assembly above the first solidus temperature such that the first solid metal TIM becomes a first liquid metal TIM; and dissolving the second solid metal TIM in the first liquid metal TIM.

In some implementations, the method further comprises: deactivating the heat generating device; and the first liquid metal TIM remains in a liquid state after deactivation of the heat generating device.

In some implementations, the liquid TIM alloy has a solidus temperature below 20° C. In some implementations, the liquid TIM alloy has a solidus temperature below 15° C. In some implementations, the liquid TIM alloy has a solidus temperature between 0° C. and 20° C. In some implementations, the liquid TIM alloy has a solidus temperature between 5° C. and 15° C. In some implementations, the liquid TIM alloy has a solidus temperature between 10° C. and 20° C.

In some implementations, the liquid TIM alloy is a single liquid metal alloy formed in-situ between the heat generating device and the heat transferring device; the single liquid metal alloy comprises one or more elemental components of each of the first metal TIM and the second metal TIM; and the single liquid metal alloy has a unique solidus point.

In one embodiment, a semiconductor comprises: a first device; a second device; and a liquid TIM alloy providing a thermal interface between the first device and the second device, the liquid TIM alloy formed by performing any of the aforementioned methods.

In one embodiment, a liquid TIM alloy is formed by a process, the process comprising: forming an assembly comprising multiple solid metal TIMs between a first device and a second device such that a first surface of the solid metal TIMs is in touching relation with a surface of the first device, and a second surface of the solid metal TIMs opposite the first surface is in touching relation with a surface of the second device, the solid metal TIMs comprising a first solid metal TIM and a second solid metal TIM; and forming the liquid TIM alloy from the solid metal TIMs by heating the assembly above a first solidus temperature of the first solid metal TIM, the liquid TIM alloy having a second solidus temperature below the first solidus temperature.

In one embodiment, a system includes: a first semiconductor component including a first solid metal TIM pre-attached to a surface of a first device, a second solid metal TIM, and a second semiconductor component including a second device. The first semiconductor component and the second semiconductor component can be formed into a semiconductor assembly by placing a first surface of the second solid metal TIM in touching relating with a surface of the second device, placing a second surface of the second solid metal TIM in touching relating with the first solid metal TIM, and forming a liquid TIM alloy from the first solid metal TIM and the second solid metal TIM by heating the first solid metal TIM or the second solid metal TIM above a first solidus temperature of the first solid metal TIM or the second solid metal TIM, the liquid TIM alloy having a second solidus temperature below the first solidus temperature. In such implementations, the second solid metal TIM is pre-attached to the surface of the second device prior to placement of the two semiconductor components. In such implementations, the first solid metal TIM and the second solid metal TIM can be a single metal or a metal alloy.

In one embodiment, a method comprises: placing a solid gallium or gallium alloy TIM between a heat generating device and a heat transferring device to form an assembly such that a first surface of the solid gallium or gallium alloy TIM is in touching relation with a surface of the first heat generating device, and a second surface of the solid gallium or gallium alloy TIM opposite the first surface is in touching relation with a surface of the heat transferring device; and after placing the solid gallium or gallium alloy TIM, activating the heat generating device to form a liquid gallium or gallium alloy TIM from the solid gallium or gallium alloy TIM.

Other features and aspects of the disclosed technology will become apparent from the following detailed description, taken in conjunction with the accompanying drawings, which illustrate, by way of example, the features in accordance with implementations of the disclosed technology. The summary is not intended to limit the scope of any inventions described herein, which are defined by the claims and equivalents.

It should be appreciated that all combinations of the foregoing concepts (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein.

### BRIEF DESCRIPTION OF THE DRAWINGS

The present disclosure, in accordance with one or more implementations, is described in detail with reference to the following figures. The figures are provided for purposes of illustration only and merely depict example implementations. Furthermore, it should be noted that for clarity and ease of illustration, the elements in the figures have not necessarily been drawn to scale.

Some of the figures included herein illustrate various implementations of the disclosed technology from different viewing angles. Although the accompanying descriptive text may refer to such views as “top,” “bottom” or “side” views, such references are merely descriptive and do not imply or require that the disclosed technology be implemented or used in a particular spatial orientation unless explicitly stated otherwise.

FIG. 1A depicts a semiconductor assembly including a first metal TIM in the TIM 1 position, and a second metal TIM in the TIM 2 position, in accordance with some implementations of the disclosure.

FIG. 1B shows the TIMs of the semiconductor assembly of FIG. 1A after a die heat source has released enough waste heat to effect the change of phase of the TIMs from solid to liquid TIMs.

FIG. 2A shows an exploded view of layers of a semiconductor device in the TIM 0 configuration, including three separate metal TIMs in the solid state, in accordance with some implementations of the disclosure.

FIG. 2B shows the semiconductor device of FIG. 2A after the solid first metal TIM has reached a temperature above its solidus point to form a liquid first metal TIM.

FIG. 2C shows the semiconductor device of FIG. 2B after both the second metal TIM and the third metal TIM have dissolved in the liquid first metal TIM.

FIG. 3A depicts a semiconductor device with both TIM 1 and TIM 2 configurations, including three separate metal TIMs in the solid state in each of the TIM 1 and TIM 2 configurations, in accordance with some implementations of the disclosure.

FIG. 3B depicts both the TIM 1 and TIM 2 configurations of the semiconductor device of FIG. 3A after the solid first metal TIM and solid fourth metal TIM have each reached a temperature above their solidus point to form a liquid first metal TIM and liquid fourth metal TIM, respectively, following activation of a chip heat source.

FIG. 3C shows the semiconductor device of FIG. 3B after both the second metal TIM and the third metal TIM have dissolved in the liquid first metal TIM to form a first liquid metal alloy, and after both the fifth metal TIM and sixth metal TIM have fully dissolved in the liquid fourth metal TIM to form a second liquid metal alloy.

The figures are not exhaustive and do not limit the present disclosure to the precise form disclosed.

### DETAILED DESCRIPTION OF THE EMBODIMENTS

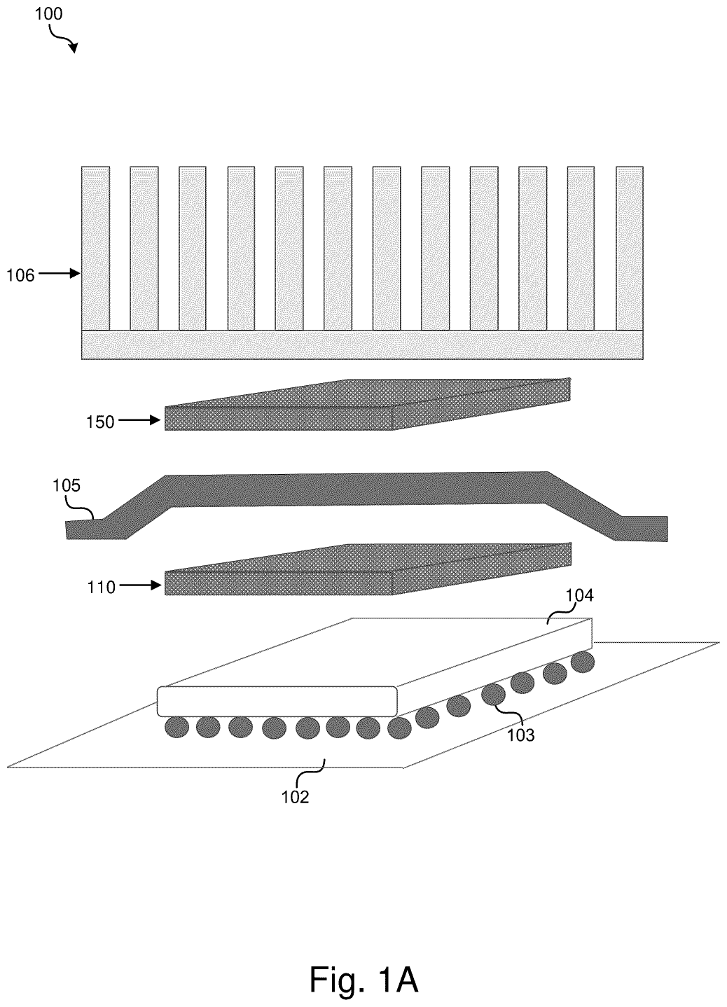

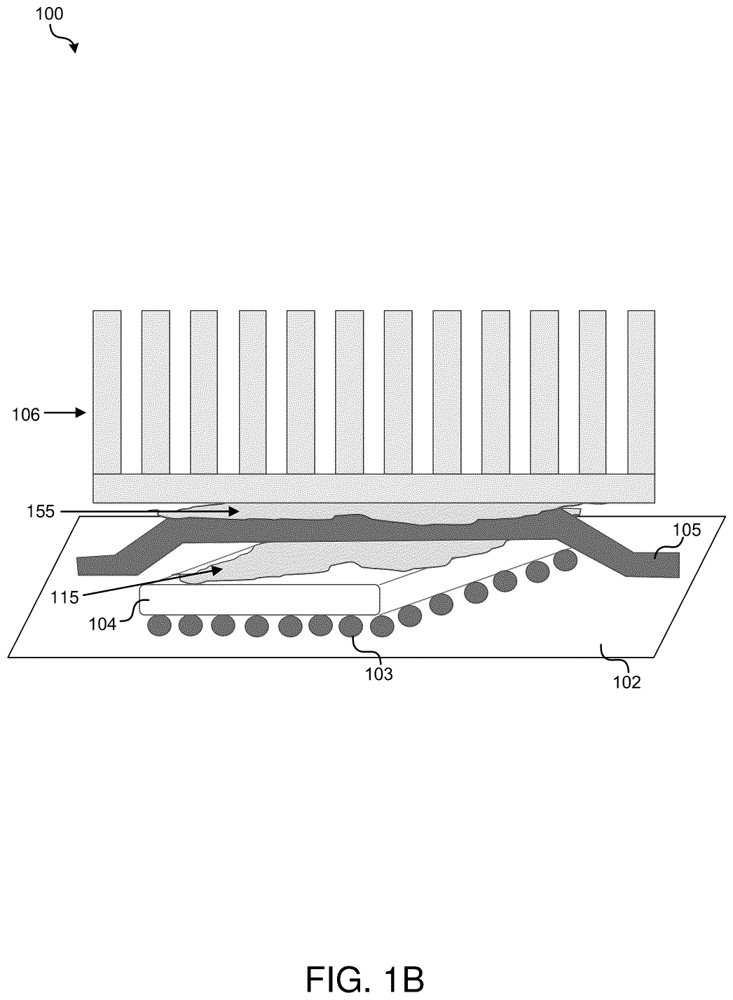

FIG. 1A depicts a semiconductor assembly 100 including a first metal TIM 110 in the TIM 1 position, and a second metal TIM 150 in the TIM 2 position, in accordance with some implementations of the disclosure. In this example, a single, solid metal (e.g., solid gallium only) is used in each position. In alternative implementation, a single, solid metal (e.g., solid gallium only) can be used in the TIM 0 position in an assembly having a TIM 0 configuration. Also depicted is a heat source 104 (e.g., a semiconductor chip), and a substrate 102 onto which the heat source is mounted within the device.

The metal TIMs can be placed while they are at a temperature below their solidus temperature such that the TIMs can be placed in solid form (e.g., using a pick and place machine), and a premature phase change does not occur prior to operation of the device. For example, each of metal TIM 110 and metal TIM 150 can be a solid block of gallium that is placed by a pick and place machine. After placement, the solid block of gallium can phase change into liquid form during operation/heating of assembly 100. To prevent a premature phase change prior to placement of the TIM metals and assembly of semiconductor assembly 100, each TIM metal can be stored in a cooler (e.g., freezer) that maintains the temperature well below the melting point of the metal. For example, in the case of gallium, the cooler may maintain the temperature well below 30° C. such as 20° C. or lower 10° C. or lower, 0° C. or lower, etc. By virtue of the first metal and second metal remaining in solid form during the assembly of the device, unwanted leakage of these metals during the assembly stage is prevented.

In the example of FIG. 1A, only one metal or metal alloy is placed in the TIM 1 and TIM 2 configurations. An example of the metal could be a solid form of gallium, which has a melting point of about 29.76° C. Gallium remains solid at room temperature, but it has a sufficiently low solidus temperature capable of changing phase during the operation of the semiconductor chip, which may provide a heat source capable of changing the solid gallium to liquid gallium. FIG. 1B shows the TIMs in the TIM 1 and TIM 2 configurations after the die heat source has released enough waste heat to effect the change of phase of the TIMs from solid to liquid TIMS 115 and 155. By virtue of the illustrated approach, the semiconductor assembly can be assembled using a pick and place machine to position the solid gallium between the heat generating and heat transferring components. As such, assembly can occur without leakage of liquid gallium, and the final configuration of the liquid gallium TIM can be activated by operating the semiconductor chip above room temperature (e.g., above 30° C.), or by applying some heat to the assembly.

One drawback of using a single metal such as gallium as a phase change TIM material, as depicted in FIGS. 1A-1B, is that upon deactivation of the device, the metal may return back to the solid state rather than remain in the liquid form. If solidification of the TIM(s) occurs after deactivating the device, it can take some time (e.g., several minutes) to return the TIM(s) to liquid form once the device is reactivated. Until the phase change occurs, the chip may operate inefficiently since the solid form of the TIM(s) results in a higher thermal surface resistivity than the liquid form of the TIM(s).

To overcome the challenges of using a single metal TIM in a device stack, some implementations of the disclosure are directed to device assembly using multiple solid TIMs, the multiple solid TIMs including at least a first TIM comprising a first metal and a second TIM comprising a second metal, where the second metal is soluble in the first metal upon activation of a heat source that raises the temperature of the first metal above its solidus point. By virtue of adding solid TIM metals that can dissolve in the first metal of the TIM to form a multi-element alloy, in-situ, the solidus point of the final/combined TIM (i.e., the multi-element alloy) can be significantly lower than the lowest solidus point of the constituent metals, and the multi-element alloy remains in liquid form after the first operation of the device. As such, the multi-element alloy can remain in liquid form even after the device is deactivated. Accordingly, the benefits of device assembly using solid metal TIMs combined with the benefits of the TIM retaining a liquid metal state can be combined.

The technology described herein can be utilized in TIM 0, TIM 1, and/or TIM 2 configurations. When a TIM is placed between the semiconductor chip and the heat sink, the configuration is referred to as TIM 0. When placed between the semiconductor device and heat spreader, the configuration is referred to as TIM 1. When placed between the heat spreader and heat sink, the configuration is referred to as TIM 2.

The technology described herein leverages the physical property of metals when alloyed together. While metals in elemental form have a unique melting point, combinations of metals in alloy form can have their own unique properties including a unique melting point unrelated to the individual constituent metals that comprise the alloy. For example, indium metal has a melting point of 156.6° C., gallium metal has a melting point of 29.76° C., and tin has a melting point of 231.9° ° C. If gallium metal comes in surface contact with indium metal and the temperature of the gallium metal is raised above its solidus temperature, the indium metal will dissolve into the gallium, forming an alloy comprising gallium and indium. At a 3:1 ratio of gallium to indium, the solidus temperature of this alloy is 15.7° C. When tin is added to the gallium and indium such that the stoichiometry is 65.5Ga 20.5In 13.0Sn, the resulting melting temperature of the alloy is 11° C.

As such, some implementations of the disclosure utilize a gallium TIM that is alloyed with one or more other metal TIMs. Many metals can be quite readily dissolved in gallium metal. For example, some implementations utilize indium, tin, zinc, and/or aluminum, all of which are soluble in gallium.

Before device assembly, the metal with the lowest solidus temperature can be separated from other metal(s) or alloy(s) to prevent the final liquid alloy from accidentally forming during shipping, etc., if the temperature exceeds that of the metal with the lowest solidus temperature. As exemplified above, often times the solidus point of a multi-element alloy can be less than the individual elements comprising the alloy. If the alloy were accidentally formed during an inadvertent temperature spike during shipping, the alloy may remain in liquid form, which would not allow for mechanical placement of the TIMs by non-dispensing/jetting means. Separation of the element with the lowest solidus temperature from the others prevents premature formation of the liquid metal alloy prior to placement of the TIM pieces into the device. In the case of a two-part TIM, for example, a final liquid alloy comprising gallium and indium, the gallium and indium could be placed separately into the device, each in solid form. In the case of a 3-part TIM, for example, gallium, indium, and tin, each could be placed separately into the device or the indium and tin could be alloyed or pressed together prior to placement such that the first metal is placed and the second and third metals are placed together as one alloy or mixture.

As such, the lowest melting point metal can be separated from the others such that the materials can be placed by a pick and place machine in solid form. Once the lowest melting point metal (e.g., gallium) melts, the other solid metals (e.g., In and Sn) can dissolve into the lowest melting point metal and form a liquid alloy. If this alloy were to form prematurely during shipping the metals would be in liquid form and could not be placed by pick and place machine.

The TIMs described herein can be formed as solid shaped pieces of metal or solder by casting, extrusion, direct metal laser sintering (DMLS), punching the shape from a foil, or using some other suitable method. Another method involves mixing powders of each element together and forming a solid piece of metal by hot or cold isostatic press.

In some implementations, to form a solid TIM preform, multiple elements can be alloyed together or pressed together as in the case of powders. To prevent premature phase change into a liquid, the element with the lowest melting point (e.g., gallium) can be excluded in this alloy or mixture of powders. For example a solid piece of gallium may be placed in a device stack up along with a separate solid metal or metal alloy or a separate shaped metal solid comprised of one or more pressed powders, or combinations thereof.

In some implementations, the TIMs may have differing shaped solid forms. For example the first metal may be in foil form and the second metal may be in sphere or wire form. In some implementations, the metal may have a patterned surface. For example, in some implementations one of the TIMs can be composed of a metal-braid-metal sandwich, which can be manufactured in the form of a foil. One such example of a foil is described with reference to U.S. Pat. Nos. 4,968,550 and 5,052,611, which describe techniques for forming an indium-braid-indium sandwich. The thermally conductive foil can be assembled as follows. A braid, i.e. a sheet of braided or woven filaments of metal, glass, or polymeric fibers can be suitably cleaned and pretreated, and coated with upper and lower layers of metal ribbon such as indium ribbon. The assembly of the braid with the upper and lower metal ribbons can be worked between upper and lower pressure rollers to produce a metal/braid/metal sandwich. The resulting sandwich is of thickness that can be greater than, equal to, or less than that of the original braid.

In some implementations, a portion of a final TIM alloy may be pre-attached to the chip, heat spreader or heat sink. For example, a solid form of a metal alloy not including the lowest melting point metal may be pre-attached to a heat transferring or heat generating component of the final semiconductor assembly. As another example, a solid form of the lowest melting point metal may be separately pre-attached to a component.

Regardless of the stack up placement order, or if the metal TIMs are pre-attached to another structure, or if the metal TIMs are formed by casting or formed by pressing metal powders, the final liquid alloy arrangement that is formed can be the same. It may be impossible to determine the placement method, the original arrangement, the method, or form of the individual TIM components once the liquid alloy is formed. These different original configurations can be very important to ensure the final liquid alloy is created with the correct stoichiometry and at the correct time after placement of the individual TIM parts. There also may be economic considerations for placement of the TIM elements in a specific configuration. For example, it may be economically preferred to pre-attach one or more of the individual alloy constituents to the chip, heat spreader, or heat sink for economic means or for ease of assembly. The metal with the lowest solidus temperature can then be placed within the stack up such that at least one side of the first metal, whether pre-attached or not, is touching at least one side of the second TIM metal or metal alloy.

In some implementations, the TIM may be composed of 3 individual TIM materials between the heat source and thermal transfer device such that at least one surface of the first TIM touches at least one side of the second TIM and the opposing side of the second TIM touches at least one side of the third TIM.

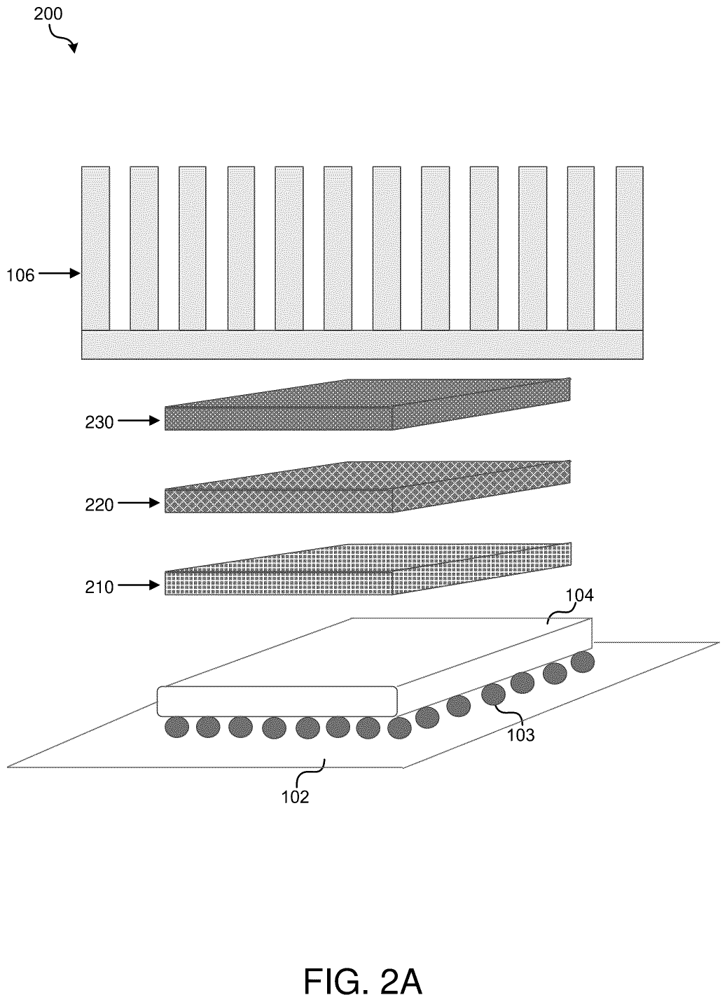

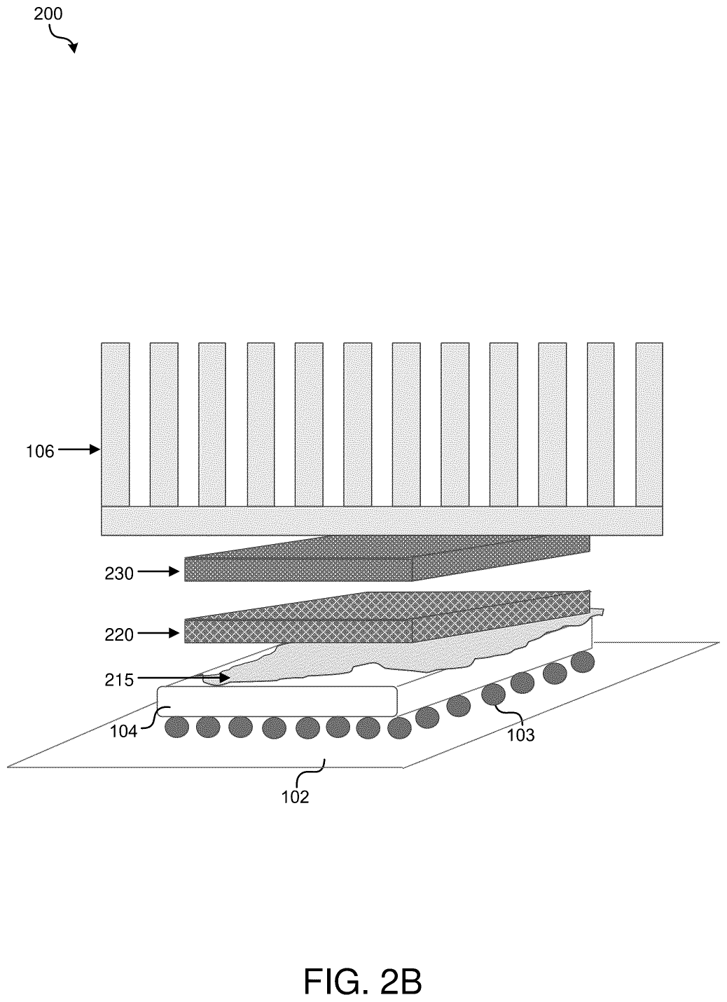

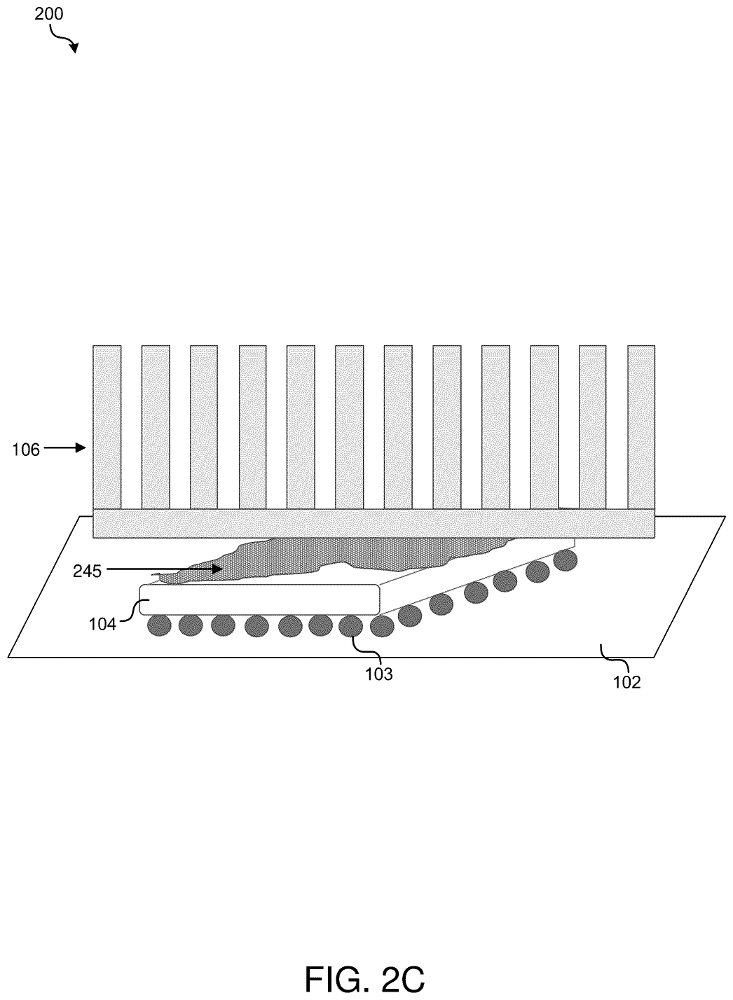

FIG. 2A shows an exploded view of layers of a semiconductor device 200 in the TIM 0 configuration, including three separate metal TIMs in the solid state, in accordance with some implementations of the disclosure. In device 200, metal TIMs 210-230 are placed between the semiconductor chip 104 and the heat sink 106. The semiconductor chip 104, which also serves as a heat source, is attached to the substrate 102 by means of reflowed solder balls 103. The solder balls 103 are in touching relation with both the substrate 102 and the semiconductor die 103 such that one hemisphere of the solder ball(s) is touching one side of the substrate and the opposing hemisphere of the solder ball(s) is touching one side of the chip 104. In this example and other semiconductor assembly examples illustrated in the figures, the TIMs are used in a chip carrier depicted as a ball grid array (BGA) assembly. However, it should be appreciated that the TIMs may be utilized to provide a TIM in other semiconductor assemblies, chip carriers, or surface-mount packaging, including, for example, land grid arrays (LGA), pin grid arrays (PGA), and the like.

The three metal TIMs can be placed following reflow of solder balls 103 such that the side of the chip 104 opposing the side touching one hemisphere of the solder balls 103 is in touching relation with one side of the first metal TIM 210. The second metal TIM 220 is placed in touching relation with the side of the first metal TIM 210 opposing the side touching the semiconductor chip 104, and the third metal TIM 230 is placed in touching relation to the second metal TIM 220 opposite the side touching the first metal TIM 210. The heat sink 106 is then placed on top of the third metal TIM 230 such that one side of the third metal TIM 230 is in touching relation with the second metal TIM 220 and the opposing side of the third metal TIM 230 is in touching relation with the heat sink 106. Although three metal TIMs are illustrated in this example, it should be appreciated that some embodiments can be implemented with two metal TIMs or more than three metal TIMs.

The first metal TIM 210, the second metal TIM 220 and the third metal TIM 230 can be placed manually or robotically (e.g., using a pick and place machine) in solid form during the assembly of the device 200. This circumvents the need to have a liquid metal TIM (i.e., the first metal TIM 210) placed by jetting or dispensing equipment. In this example, the first metal TIM 210 has the lowest solidus point of the three TIMs. Upon activation of the device heat source, the first metal TIM 210 is liquified upon reaching a temperature above its solidus point.

FIG. 2B shows the semiconductor device 200 after the solid first metal TIM 210 has reached a temperature above its solidus point to form a liquid first metal TIM 215. This can occur following activation of the chip 104 heat source. FIG. 2C shows the semiconductor device 200 after both the second metal TIM 220 and the third metal TIM 230 have dissolved in liquid first metal TIM 215. Once the second metal TIM 220 and the third metal TIM 230 have fully dissolved, a single alloy is formed in-situ comprised of the first metal TIM 215, the second metal TIM 220, and the third metal TIM 230, depicted in FIG. 2C as liquid metal alloy TIM 245. The result is a liquid alloy with a solidus point lower than the solidus point of the first metal TIM 210 on its own.

For example, at certain ratios of gallium to indium, the solidus point of GaIn can be lower than the solidus point of Ga. At certain ratios of gallium, indium, and tin, the solidus point of GaInSn can be even lower than solidus point of GaIn. For instance, where the liquid metal alloy 245 is comprised of a ratio of about 68.5% Ga, 21.5% In and 10% Sn, the solidus point of the alloy 245 is about 11° C., which compared with the solidus point of the first metal TIM 210 alone (gallium) is 19° C. lower and remains liquid at room temperature. Assuming the device stays at room temperature or above, or minimally above 11° C., the metal alloy TIM 245 will remain in liquid form regardless of whether or not the chip heat source 104 is re-energized after its initial power cycling.

Although in the example of FIGS. 2A-2C, the first metal TIM 215 could be gallium, the second metal TIM 220 could be indium, and the third metal TIM 230 could be tin, this is by no means an exhaustive list of metal TIM options. Other TIM configurations are possible provided that each TIM is in touching relation with at least one side of another TIM in the stackup. In addition, at least some of the placed TIMs can be alloys comprised of more than one metal.

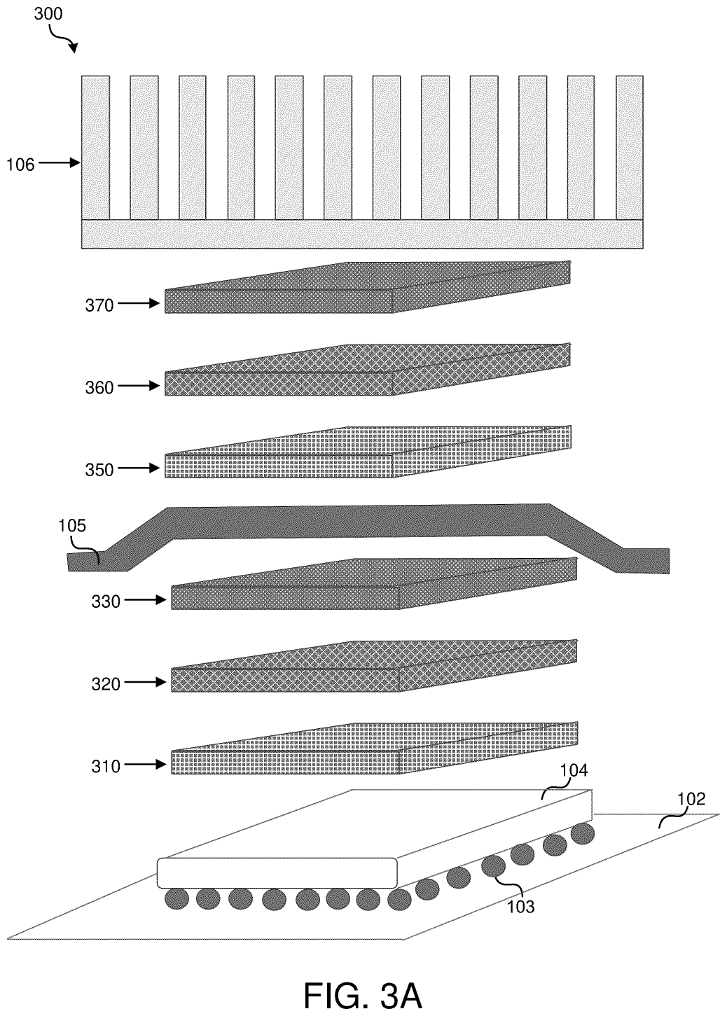

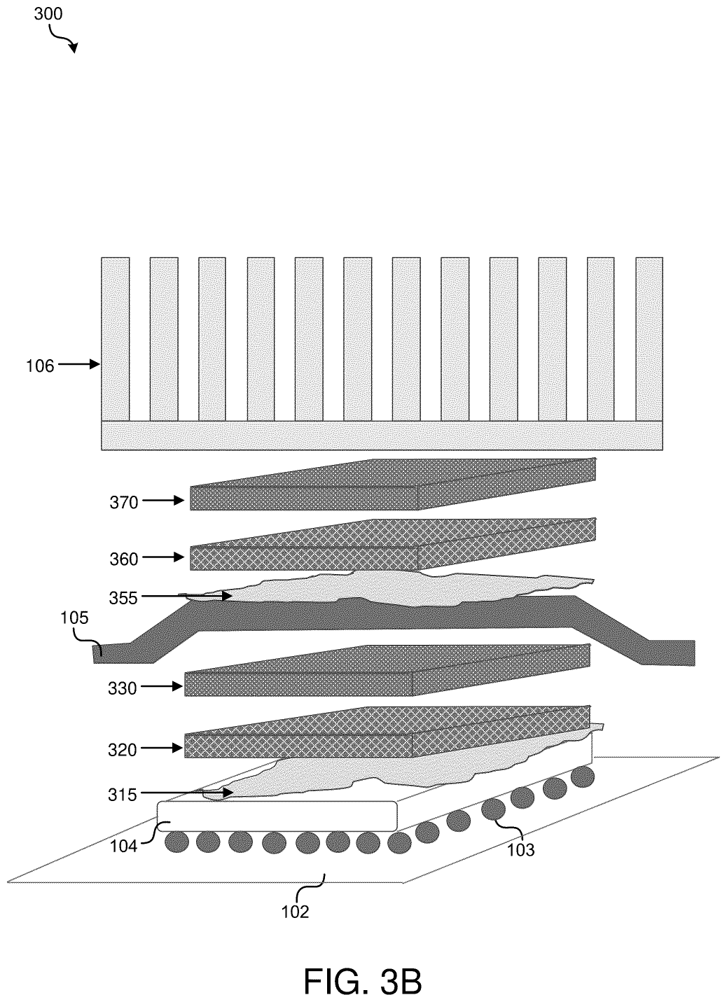

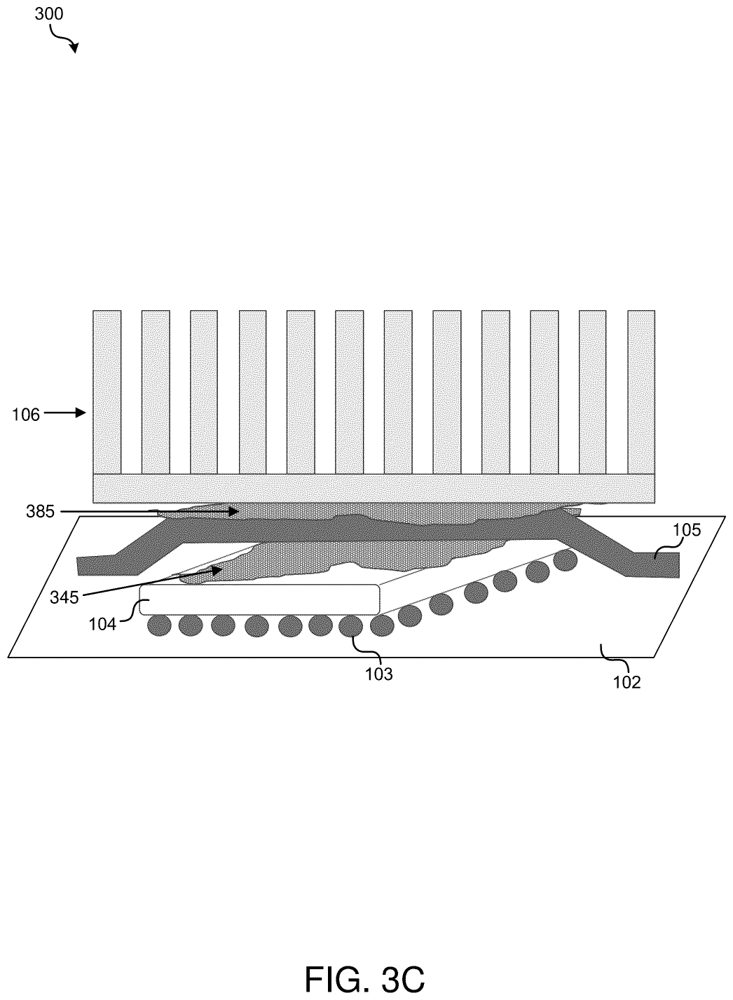

FIG. 3A depicts a semiconductor device with both TIM 1 and TIM 2 configurations, including three separate metal TIMs in the solid state in each of the TIM 1 and TIM 2 configurations, in accordance with some implementations of the disclosure. In the TIM 1 position, the first metal TIM 310, the second metal TIM 320 and the third metal TIM 330 can be placed manually or robotically in solid form during the assembly of the device 300, as can the fourth metal TIM 350, the fifth metal TIM 360, and the sixth metal TIM 370 located in the TIM 2 position. This circumvents the need to have a liquid metal TIM placed by jetting or dispensing equipment. In TIM 1, the first metal TIM 310 has the lowest melting point, and in TIM 2 the fourth metal TIM 350 has the lowest melting point.

In this configuration, the TIM 1 metals 310, 320, 330 are placed between the semiconductor chip 104 and the heat spreader or lid 105. The TIM 2 metals 350, 360, 370 are placed between the semiconductor heat spreader or lid 105 and the heat sink 106. Although three metal TIMs for each of TIM 1 and TIM 2 are illustrated in this example, it should be appreciated that some embodiments can be implemented with two metal TIMs or more than three metal TIMs for TIM 1 and/or TIM 2.

Upon activation of the device heat source, the first metal TIM 310 and the fourth metal TIM 350 undergo a phase change upon reaching a temperature above the solidus point of the aforementioned metal TIMs, respectively. In the configuration of FIG. 3A, semiconductor chip 104 also serves as the heat source. The chip 104 is attached to the substrate 102 by means of reflowed solder balls 103. The solder balls 103 are in touching relation with both the substrate 102 and the semiconductor die 103 such that one hemisphere of the solder ball(s) is touching one side of the substrate and the opposing hemisphere of the solder ball(s) is touching one side of the chip 104.

FIG. 3B depicts both the TIM 1 and TIM 2 configurations of semiconductor device 300 after the solid first metal TIM 310 and solid fourth metal TIM 350 have each reached a temperature above their solidus point to form a liquid first metal TIM 315 and liquid fourth metal TIM 355, respectively, following activation of the chip 104 heat source. As an example, in the TIM 1 position, the liquid first metal TIM 315 could be gallium, the second metal TIM 320 could be indium, and the third metal TIM 330 could be tin. In the TIM 2 position, the liquid fourth metal TIM 355 could be gallium, the fifth metal TIM 360 could be indium and the sixth metal TIM 370 could be tin. Other TIM metal options and configurations are possible provided that each TIM is in touching relation with at least one side of another TIM within each individual TIM 1 or TIM 2 configuration.

FIG. 3C shows the semiconductor device 300 after both the second metal TIM 320 and the third metal TIM 330 have dissolved in liquid first metal TIM 315 to form liquid metal alloy 345, and after both the fifth metal TIM 360 and sixth metal TIM 370 have fully dissolved in liquid fourth metal TIM 355 to form liquid metal alloy 385. Each of the formed liquid metal alloys 345, 385 can have a solidus point below room temperature, and lower than the lowest solidus point of their constituent metals. As such, assuming the device stays at room temperature or above, the liquid metal alloys 345 and 385 can remain in liquid form regardless of whether or not the chip heat source 104 is re-energized after its initial power cycling.

The descriptions and drawings are by no means the only configurations that could be utilized. For example, to achieve the final stoichiometry or volume of liquid metal in the device stackup of liquid metal alloy TIM 345 or 385, respectively, additional layers of solid metal may be employed. For example, a solid piece of indium metal may be sandwiched between two solid pieces of gallium. This method can maximize surface contact of the two metals such that when the temperature rises above the solidus temperature of the gallium metal, the indium metal will dissolve into the gallium, forming a gallium-indium liquid alloy in-situ. It may also be beneficial in achieving the final desired stoichiometry of the liquid metal with a defined melting temperature or melting temperature range. Additional metals or metal alloys other than those described in the examples could be employed. Suitable metals capable of dissolving in gallium include In, Sn, Zn, Bi, Au, Ag, Cu, W, Ni, Cr, Mo, Ti, Cd, and Pb.

In the examples described herein, the final alloy TIM formed in-situ need not be a eutectic alloy. For example it may be preferable to have an indium-rich non-eutectic alloy of Ga and In or Ga, In, and Sn. The increased content of indium can increase the thermal conductivity of the final alloy and can also create a plastic range of the final alloy that increases the viscosity and prevents pump out of the liquid metal during operation.

The final alloy of the liquid metal may have one component, two components or many components. For example if the desired liquid alloy is gallium, indium, tin, and zinc then separate solid shaped pieces of each element may be placed separately in the stackup and alloyed once the gallium reaches a temperature above its solidus temperature, thereby dissolving the other metals into the melt pool of gallium.

In other implementations, the individual metals can be pre-attached together in solid form and placed onto the device setup as a single piece. For example the metals can be pressed together as foils such that the metals are cold-welded together yet each retains its individual characteristics until the metal with the lowest solidus temperature is melted and the other metals begin to dissolve.

The metals need not be in planar or in foil form as depicted in the drawings. The metal(s) with the higher solidus points may be discrete spheres, or cubes, or any other shape that may be placed singularly or in multiples in the same layer.

In some implementations, it may be preferable for one or more metals (e.g., those having discrete shapes as discussed above) to be non-soluble in the metal TIM with the lowest solidus point. If one of the layers remains partially or fully in solid form, this could be beneficial because the insoluble metal(s) can serve as a standoff to control the bond line thickness between the chip and the heat sink in the TIM 0 configuration, the bond line thickness between the chip and the lid in the TIM 1 configuration, or the bond line thickness between the lid and the heat sink in the TIM 2 configuration.

In some implementations, the metals that are insoluble in the metal with the lowest solidus point may be first coated in a metal that is soluble in the metal with the lowest solidus point. For example the standoff/bond line thickness control metals could first be coated in indium as a means to cold weld the discrete shapes to the other TIM metals in the device or to the devices components themselves such as the chip 104, lid 105 or heatsink 106. The coating can dissolve in the liquid metal while the insoluble metal remains solid and serves to control the bond line thickness.

While various embodiments of the disclosed technology have been described above, it should be understood that they have been presented by way of example only, and not of limitation. Likewise, the various diagrams may depict an example architectural or other configuration for the disclosed technology, which is done to aid in understanding the features and functionality that can be included in the disclosed technology. The disclosed technology is not restricted to the illustrated example architectures or configurations, but the desired features can be implemented using a variety of alternative architectures and configurations. Additionally, with regard to flow diagrams, operational descriptions and method claims, the order in which the steps are presented herein shall not mandate that various embodiments be implemented to perform the recited functionality in the same order unless the context dictates otherwise.

Although the disclosed technology is described above in terms of various exemplary embodiments and implementations, it should be understood that the various features, aspects and functionality described in one or more of the individual embodiments are not limited in their applicability to the particular embodiment with which they are described, but instead can be applied, alone or in various combinations, to one or more of the other embodiments of the disclosed technology, whether or not such embodiments are described and whether or not such features are presented as being a part of a described embodiment. Thus, the breadth and scope of the technology disclosed herein should not be limited by any of the above-described exemplary embodiments.

Terms and phrases used in this document, and variations thereof, unless otherwise expressly stated, should be construed as open ended as opposed to limiting. As examples of the foregoing: the term “including” should be read as meaning “including, without limitation” or the like; the term “example” is used to provide exemplary instances of the item in discussion, not an exhaustive or limiting list thereof; the terms “a” or “an” should be read as meaning “at least one,” “one or more” or the like; and adjectives such as “conventional,” “traditional,” “normal,” “standard,” “known” and terms of similar meaning should not be construed as limiting the item described to a given time period or to an item available as of a given time, but instead should be read to encompass conventional, traditional, normal, or standard technologies that may be available or known now or at any time in the future. Likewise, where this document refers to technologies that would be apparent or known to one of ordinary skill in the art, such technologies encompass those apparent or known to the skilled artisan now or at any time in the future.

The presence of broadening words and phrases such as “one or more,” “at least,” “but not limited to” or other like phrases in some instances shall not be read to mean that the narrower case is intended or required in instances where such broadening phrases may be absent.

Additionally, the various embodiments set forth herein are described in terms of exemplary block diagrams, flow charts and other illustrations. As will become apparent to one of ordinary skill in the art after reading this document, the illustrated embodiments and their various alternatives can be implemented without confinement to the illustrated examples. For example, block diagrams and their accompanying description should not be construed as mandating a particular architecture or configuration.

It should be appreciated that all combinations of the foregoing concepts (provided such concepts are not mutually inconsistent) are contemplated as being part of the inventive subject matter disclosed herein. In particular, all combinations of claimed subject matter appearing in this disclosure are contemplated as being part of the inventive subject matter disclosed herein.

What is claimed is:

1. A method, comprising:
forming an assembly comprising multiple solid metal thermal interface materials (TIMs) between a first device and a second device such that a first surface of the solid metal TIMs is in touching relation with a surface of the first device, and a second surface of the solid metal TIMs opposite the first surface is in touching relation with a surface of the second device, the solid metal TIMs comprising a first solid metal TIM and a second solid metal TIM; and
forming a liquid TIM alloy from the solid metal TIMs by heating the assembly above a first solidus temperature of the first solid metal TIM, the liquid TIM alloy having a second solidus temperature below the first solidus temperature.

2. The method of claim 1, wherein:
the second solid metal TIM has a third solidus temperature higher than the first solidus temperature of the first solid metal TIM;
the first solid metal TIM becomes a first liquid metal TIM when the assembly is heated above the first solidus temperature; and
forming the liquid TIM alloy comprises dissolving the second solid metal TIM in the first liquid metal TIM.

3. The method of claim 2, wherein:
the multiple solid metal thermal interface materials comprise a third solid metal TIM having a fourth solidus temperature higher than the first solidus temperature of the first solid metal TIM; and
forming the liquid TIM alloy comprises dissolving the second solid metal TIM and the third solid metal TIM in the first liquid metal TIM.

4. The method of claim 1, wherein: the multiple solid metal thermal interface materials comprise a third solid metal TIM including a first metal that is not soluble in the liquid TIM alloy, the first metal that is not soluble in the liquid controlling a bond line thickness of the assembly after the liquid TIM alloy is formed.

5. The method of claim 4, wherein:
the third solid metal TIM further includes a second metal coating the first metal that is not soluble in the liquid TIM alloy; and
forming the liquid TIM alloy comprises dissolving the second metal in the first liquid metal TIM.

6. The method of claim 1, wherein:
forming the assembly comprises: placing the first solid metal TIM and the second solid metal TIM between the first device and the second device such that the first solid metal TIM is in touching relation with the second solid metal TIM; and
the second solid metal TIM has a third solidus temperature higher than the first solidus temperature of the first solid metal TIM.

7. The method of claim 6, wherein:
the multiple solid metal thermal interface materials comprise a third solid metal TIM having a fourth solidus temperature higher than the first solidus temperature of the first solid metal TIM; and
forming the assembly comprises: placing the third solid metal between the first device and the second device such that the third solid metal TIM is in touching relation with the first solid metal TIM.

8. The method of claim 1, wherein:
prior to forming the assembly, the second solid metal TIM is attached to the surface of the first device or the surface of the second device; and
forming the assembly comprises: placing the first solid metal TIM in touching relation with the second solid metal TIM between the first device and the second device.

9. The method of claim 1, wherein:
prior to forming the assembly, the first solid metal TIM is attached to the surface of the first device or the surface of the second device; and
forming the assembly comprises: placing the second solid metal TIM in touching relation with the first solid metal TIM between the first device and the second device.

10. The method of claim 1, wherein the liquid TIM alloy comprises In, Sn, Zn, Bi, Au, Ag, Cu, W, Ni, Cr, Mo, Ti, Cd, or Pb.

11. The method of claim 1, wherein the first solid metal TIM comprises gallium or a gallium alloy.

12. The method of claim 11, wherein the second solid metal TIM comprises indium or an indium alloy.

13. The method of claim 12, wherein:
the multiple solid metal thermal interface materials comprise a third solid metal TIM comprising tin or a tin alloy; and
the liquid TIM alloy comprises gallium, indium, and tin.

14. The method of claim 1, wherein the first device is a heat generating device, and the second device is a heat transferring device.

15. The method of claim 14, wherein the heat generating device is a semiconductor die, and the heat transferring device is a semiconductor package lid or heat sink.

16. The method of claim 14, wherein: forming the liquid TIM alloy from the solid metal TIMs comprises:
activating the heat generating device to heat the assembly above the first solidus temperature such that the first solid metal TIM becomes a first liquid metal TIM; and
dissolving the second solid metal TIM in the first liquid metal TIM.

17. The method of claim 16, wherein:
the method further comprises: deactivating the heat generating device; and
the first liquid metal TIM remains in a liquid state after deactivation of the heat generating device.

18. The method of 16, wherein the liquid TIM alloy has a solidus temperature below 20° C.

19. The method of claim 14, wherein:
the liquid TIM alloy is a single liquid metal alloy formed in-situ between the heat generating device and the heat transferring device;
the single liquid metal alloy comprises one or more elemental components of each of the first metal TIM and the second metal TIM; and
the single liquid metal alloy has a unique solidus point.

20. A liquid thermal interface material (TIM) alloy formed by a process, the process comprising:
forming an assembly comprising multiple solid metal TIMs between a first device and a second device such that a first surface of the solid metal TIMs is in touching relation with a surface of the first device, and a second surface of the solid metal TIMs opposite the first surface is in touching relation with a surface of the second device, the solid metal TIMs comprising a first solid metal TIM and a second solid metal TIM; and
forming the liquid TIM alloy from the solid metal TIMs by heating the assembly above a first solidus temperature of the first solid metal TIM, the liquid TIM alloy having a second solidus temperature below the first solidus temperature

21. A method, comprising:
placing a solid gallium or gallium alloy thermal interface material (TIM) between a heat generating device and a heat transferring device to form an assembly such that a first surface of the solid gallium or gallium alloy TIM is in touching relation with a surface of the first heat generating device, and a second surface of the solid gallium or gallium alloy TIM opposite the first surface is in touching relation with a surface of the heat transferring device; and
after placing the solid gallium or gallium alloy TIM, activating the heat generating device to form a liquid gallium or gallium alloy TIM from the solid gallium or gallium alloy TIM.
